(19) United States
(12) Patent Application Publication
(10) Pub. No.: US 2009/0108267 A1
(43) Pub. Date: Apr. 30, 2009

(54) COMPOSITE LIGHT-EMITTING-DIODE PACKAGING STRUCTURE

(76) Inventor: Pai-Ling Sung, Taipei City (TW)

Correspondence Address: RABIN & Berdo, PC, 1101 14TH STREET, NW, SUITE 500, WASHINGTON, DC, 20005, US

(21) Appl. No.: 11/926,361

(22) Filed: Oct. 29, 2007

(51) Int. Cl. H01L 33/00

(52) U.S. Cl. 257/88; 257/100; 257/E33.059

(57) ABSTRACT

A composite light-emitting-diode (LED) packaging structure includes an upper LED package structure and a lower LED package structure packaged integrally together. The upper LED package structure includes an upper substrate having a hollow structure and an upper LED transparent chip in the hollow structure and enclosed from top to bottom by a light transmitting filling material. The lower LED package structure includes a lower substrate and a lower LED transparent chip on the lower substrate, packaged in the hollow structure and having a light transmitting protection layer.

### BACKGROUND

1. Field of the Invention

The invention relates to a light-emitting-diode (LED) packaging structure, and in particular to a composite light-emitting-diode packaging structure.

2. Related Art

Presently, the white light light-emitting-diode is the most promising LED-based product used for illumination, and it has great potential for development in the illumination device industry. Compared with the conventional tungsten filament light bulb emitting incandescent light and fluorescent lamp, the LED has the benefit of small size (so that a plurality of multiple-type LEDs can be integrally packaged together into one piece), low heat dissipation (with no heat radiation), lower power consumption (low actuation current and voltage), long service life span (more than 10,000 hours), fast response (so that it can be operated at high frequencies), environment protection (shock resistant, impact resistant, recyclable and non-polluting), and flat packaging so that it can be light weight, have a thin profile and compact size. Thus, the LED is does not have the disadvantages of being brittle, having high power consumption with the incandescent light bulb and mercury pollution with the disposed fluorescent lamp. As such it is regarded as a potential replacement for the convention illumination device over the next 10 years.

With the rapid progress of LED manufacturing technology and the development of new materials (nitride crystal and fluorescent powder), the functions and performance of the white light LED solid state semiconductor light source are constantly improved and put to actual application. The so-called white light is a mixture of lights of various colors. Usually, white light visible to the human eye is a combination of lights of at least two different colors, such as the lights of two wavelengths (blue light+yellow light) or three wavelengths (blue light+green light+red light). Presently, the commercialized LED light source is made of a blue light LED single chip and YAG yellow fluorescent powder; i.e., the LED of Nichia Chemical is made by coating a layer of YAG fluorescent material on an InGaN chip of 460 nm blue light. In operation, blue light emitted by this type of LED is irradiated on the fluorescent material to produce 555 nm yellow light complementary to blue light, then the complementary blue light and yellow light thus produced are mixed and combined into white light visible to the human eye by making use of a lens. Alternatively, lights of three different wavelengths produced by the blue light chip, green light chip, and red light chip are mixed and combined into white light through the specially designed packaging structure. In addition, the LED light source made of an inorganic ultra violet chip and red, green, and blue fluorescent powder is of superior quality and is promising in this field.

At present, the light source made of the blue light single chip LED and yellow fluorescent powder, or the light source made of three-different-light-chip-LEDs having a specially designed package, have their respective shortcomings and limitations. For example, the former has the problem that light emitted by the fluorescent powder deteriorates with time, thus reducing the precision of the white light it produces. The problem with the latter is that the utilization of chips of three different lights raises the production cost significantly.

Therefore, the research and development of an LED chip that may be used to produce white light of superior quality while reducing its production cost is the most important task in this field.

### SUMMARY OF THE INVENTION

In view of the above-mentioned problems and shortcomings of the prior art, the object of the invention is to provide a composite LED packaging structure, which can be used to produce a single wavelength light source by making use of the packaging structure of the upper and lower LED chips. Through the application of packaging structure of the invention, the cooperating upper and lower LED chips are selected depending on the wavelength of light source required. For instance, the upper LED chip can be the yellow light LED chip, and the lower LED chip can be the blue light LED chip, and as such producing the white light source required.

In addition, through the various circuit designs on the upper and lower LED chips, which can be controlled to emit light separately or simultaneously, the magnitude of respective currents flowing through the chips can be controlled to produce the variations of the mixed color, thus achieving the flexibility and versatility of the composite LED packaging structure of the invention.

Therefore, to achieve the above-mentioned objective, the invention provides a composite LED packaging structure, including: an upper LED packaging structure, containing an upper substrate having an hollow structure; an upper LED transparent chip disposed in the hollow structure and fixed therein by a light transmitting filling material; and a lower LED packaging structure integrally formed with the upper LED packaging structure, including a lower substrate; and a lower LED chip disposed on the lower substrate, packaged in the hollow structure and having a light transmitting protection layer.

Furthermore, the lower LED packaging structure is formed by adhering the light transmitting protection layer to the light transmitting filling material and/or adhering the lower substrate to the upper substrate.

Moreover, the upper LED transparent chip can be electrically connected to the upper substrate through more than one connection wire. The lower LED transparent chip can also be connected electrically to the lower substrate through more one connection wire, and the lights emitted by the two chips may be complementary lights, for example, blue light and yellow light.

The light transmitting filling material and the light transmitting protection layer may be formed integrally as the cover body of the composite LED structure.

Further scope of the applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given below, which is for illustration only and thus is not limitative of the invention.

FIG. 1 is a schematic diagram of the structure of the composite LED packaging structure before packaging according to a preferred embodiment of the invention;

FIG. 2 is a schematic diagram of the structure of the composite LED packaging structure after packaging according to a preferred embodiment of the invention;

FIG. 3 is a schematic diagram of the structure of the composite LED packaging structure after packaging according to another preferred embodiment of the invention;

FIG. 4 is a schematic diagram of the structure of the composite LED packaging structure after packaging according to yet another preferred embodiment of the invention;

FIG. 5 is a schematic diagram of the structure of the composite LED packaging structure after packaging according to another preferred embodiment of the invention; and

FIG. 6 is a schematic diagram of the top view of the composite LED packaging structure as shown in FIG. 2.

### DETAILED DESCRIPTION OF THE INVENTION

The purpose, construction, features, and functions of the invention can be understood more thoroughly through the following detailed description with reference to the attached drawings.

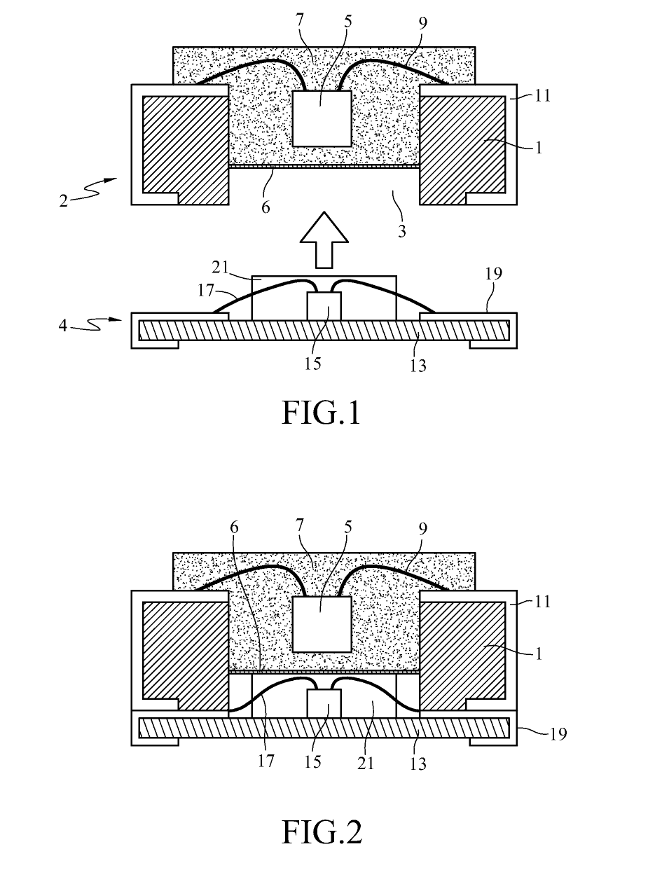

Refer to FIGS. 1 & 2, which show schematic diagrams of the structure of the composite LED packaging structure before and after packaging according to a preferred embodiment of the invention.

As shown in FIGS. 1 & 2, the composite LED packaging structure includes two LED package portions: an upper LED package structure 2 and a lower LED package structure 4, and the LED chip 15 of the lower LED package structure 4 is connected to the end portion of LED chip 5 of the upper LED package structure 2. The structures and functions of the various components are described as follows:

The upper LED package structure 2 includes: an upper substrate 1 having a hollow structure 3; an upper LED chip 5 disposed in the hollow structure 3 and fixed into the structure by the light transmitting filling material from top to bottom thus forming the cover 7. The cover 7 is made of light transmitting material so that the upper LED chip 5 may emit light in upward and downward directions.

The upper substrate 1, which can be a metal substrate or a non-metal substrate, is provided with the connection pad 11 or the electrical pattern on its outer surface for electrically connecting to the LED chip 5. The respective connection pads 11 or electrical patterns are not connected to each other and are in an insulated state. The connection wire 9 may be coated with a conductive glue (not shown), and is used to connect between the connection pad 11 and the LED chip 5. To facilitate welding and adhesion, the conduction glue usually is made of one of the following: gold, silver, tin, chromium, nickel, or an alloy thereof. Since gold is expensive and the effects of its reflection are not entirely satisfactory, presently it is not used very often.

The upper LED chip 5 can be any commercially available chip of various colors used in the prior art; however, it must be transparent or must be able to transmit light on its upper and lower surface in order to provide light in upward and downward directions.

In addition, the lower LED package structure 4 is provided with a lower substrate 13, and a lower LED chip 15 disposed on the substrate 13.

The lower substrate 13, which can be a metal substrate or a non-metal substrate, is provided with the connection pad 19 or the electrical pattern on its outer surface for electrically connecting to the LED chip 15. The respective connection pads 19 or electrical patterns are not connected to each other and are in an insulated state. If the connection pad 19 is used, then the connection wire 17 coated with a conductive glue (not shown) is utilized to connect between the connection pad 19 and the LED chip 15. To facilitate welding and adhesion, the conduction glue is usually made of one of the following: gold, silver, tin, chromium, nickel, or an alloy thereof. Since gold is expensive and the effects of its reflection are not entirely satisfactory, presently it is not used very often.

The lower LED chip 15 can be any commercially available chip of various colors used in the prior art.

Moreover, the cover body 7 is made of a light transmitting material and is formed by filling the filling material on top of the upper LED chip 5 and the connection wire 9 disposed in the hollow structure 3. Usually, the cover body 7 is made by a low pressure modeling technique or an encapsulating technique.

In addition, in the assembly of the upper LED package structure 2 and the lower LED package structure 4 another cover layer such as a light transmitting protection layer 21 is provided to fulfill the protection function of the LED chip. The light transmitting protection layer 21 is also made of light transmitting material, and it is realized through the low pressure modeling technique or the encapsulated technique.

Furthermore, the light transmitting material mentioned above may be epoxy resin.

The bonding process of the upper and lower LED package structures are described in detail as follows.

Upon finishing the assembly of the upper and lower LED package structures 2 and 4 respectively, align the lower LED package structure 4 with the hollow portion of the upper LED structure 2, then bond the upper substrate 1 and the lower substrate 13 or bond the light transmitting protection layer 21 and the cover body 7 together by making use of an adhesive glue 6, thus realizing the composite LED packaging structure of the invention.

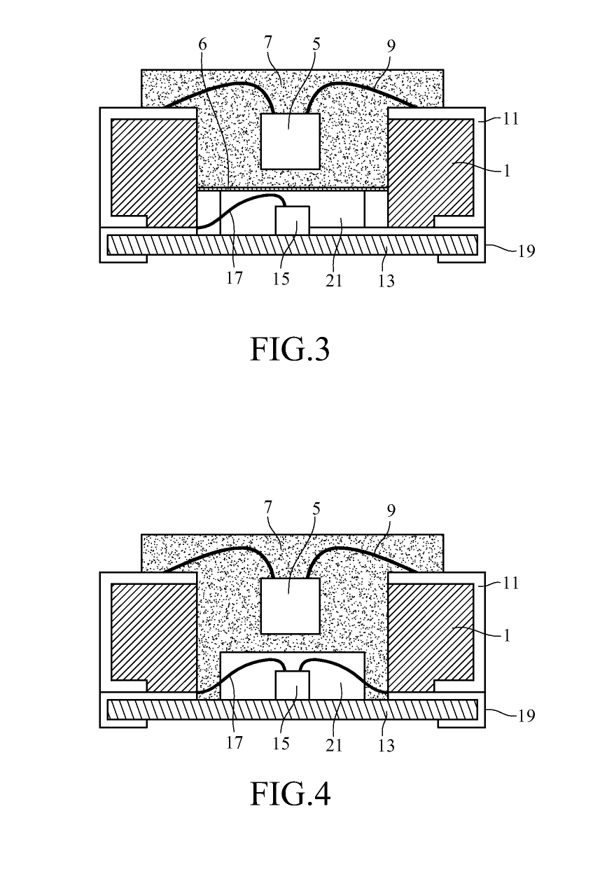

Furthermore, the lower LED package structure mentioned above may be made into a Surface Mount Device (SMD) configuration, wherein the chip may directly contact the connection pad 19 or the circuit pattern to establish electrical connection, and an additional connection wire 17 is connected to the connection pad on the other side, thus realizing the composite LED packaging structure as shown in FIG. 3.

FIG. 4 shows a schematic diagram of the structure of the composite LED packaging structure after packaging according to yet another preferred embodiment of the invention. Upon aligning the lower LED package structure 4 with the hollow portion 3 of the upper LED package structure 2, the light transmitting filling material is used to fill in the hollow portion 3 to cover the upper and lower LED chips 5 and 15 and the connection wires 9 and 17 so that the upper LED package structure and the lower LED package structure are bonded together by the integrally formed cover body 7.

In the above-mentioned structure, the bonding of the upper and lower substrates 1 and 13 can be made through the respective connection pads 11 and 19.

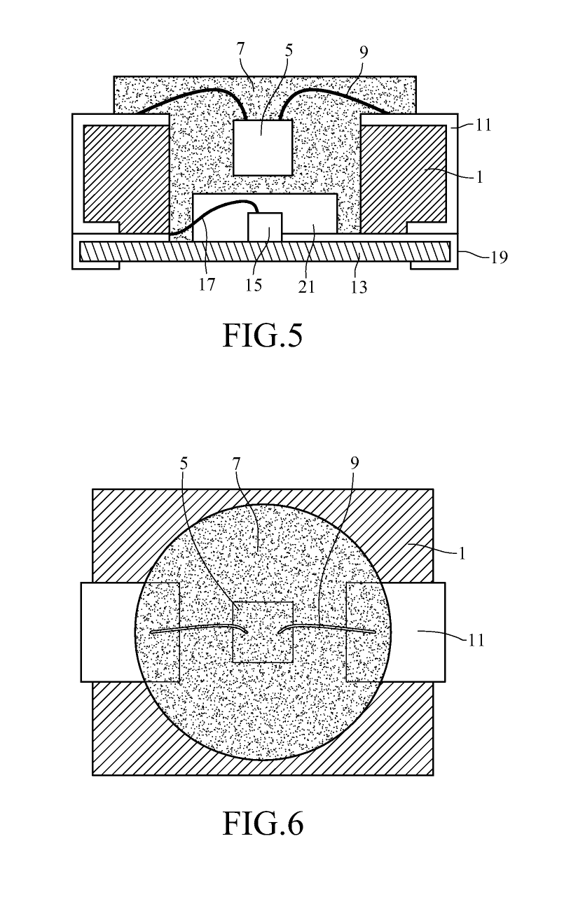

Similarly, as shown in FIG. 5, the lower LED package structure used in the composite LED packaging structure as shown in FIG. 4 may also be made into the SMD configuration. In such a structure, only one connection wire is provided, and the electrical connection is provided by direct contact between the chip and the connection pad 19 or the circuit pattern.

More specifically, the circuit design of the upper and lower LED package structures 2 and 4 are realized depending on actual requirements. For example, the circuit designs of the upper and lower LED package structures 2 and 4 may be realized in a series or parallel manner. Furthermore, in the upper and lower LED package structures 2 and 4, the circuits may be designed to achieve the simultaneous emission of light, thus realizing the mixing of lights, or alternatively the circuits of the respective structures may be designed so that they can emit light simultaneously or otherwise depending on requirements. The circuit designs mentioned above are well known in the art, and thus will not be described here.

Finally, refer to FIG. 6, which is a schematic diagram of the top view of the composite LED packaging structure as shown in FIG. 2. There is a cover body 7 covering the substrate and the hollow portion, and the light emitted by the corresponding upper and lower LED chips is transmitted and emitted through the cover body 7, thus constituting the packaging structure of light emission in a single direction. The cover body 7 shown in FIG. 6 is round shaped; however, it may also be a rectangular shaped cover body. In fact, any shape cover body can be used to achieve the objective of the invention, and the embodiment of the invention in not intended to restrict the scope of the invention.

According to the above description, the composite LED packaging structure of the invention can be utilized to mix lights of two wavelengths and transmit the mixed light through the cover body in a single direction by making the lower LED package structure align with the upper LED package structure. Therefore, through the application of the invention, the light source of the desired wavelength can be obtained through the matching and cooperation of the upper and lower LED package structures. For instance, when the lower LED package structure is used to produce blue light, and the upper LED package structure is used to produce yellow light, then white light is emitted and obtained through the cover body. When the lower LED package structure is used to produce blue light, and the upper LED package structure is used to produce red light, then violet light is emitted and obtained through the cover body. Furthermore, when the lower LED package structure is used to produce green light, and the upper LED package structure is used to produce red light, then yellow light is emitted and obtained through the cover body.

In addition, through the separate circuit designs of the upper and lower LED packaging structures, not only can mixed light of different wavelengths be obtained from the composite LED package structure through the cover body, but the respective light emitted by the upper LED package structure or the lower LED package structure may also be obtained through the cover body.

Summing up the above description, in the invention the two upper and lower LED chips are utilized to produce the mixed white light without the problem of the prior art that the light emitting capability of the fluorescent powder deteriorates with time, or that three LED chips are required to produce the mixed light. Thus the production cost of the composite LED packaging structure of the invention can be reduced significantly. In addition, through the different designs of the respective circuits, the upper and lower LED chips may be designed to emit light separately or simultaneously, thus achieving the flexibility and versatility in the application of the invention.

Furthermore, through the utilization of the invention, better light emitting effects can be obtained through the matching and cooperation of the properly selected upper and lower LED package structures depending on actual requirements.

Knowing the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A composite light-emitting-diode (LED) packaging structure, comprising:
an upper LED package structure, comprising:
an upper substrate having a hollow structure; and
an upper LED transparent chip, provided in said hollow structure and enclosed from top to bottom by means of a light transmitting filling material and fixed therein; and
a lower LED package structure, comprising:
a lower substrate; and
a lower LED transparent chip, provided on said lower substrate, and packaged in said hollow structure and having a light transmitting protection layer.

2. The composite light-emitting-diode (LED) packaging structure of claim 1, wherein the lights emitted by said upper LED transparent chip and said lower LED transparent chip are complementary lights.

3. The composite light-emitting-diode (LED) packaging structure of claim 1, wherein the lights emitted by said upper LED transparent chip and said lower LED transparent chip are complementary lights and are mixed into white light.

4. The composite light-emitting-diode (LED) packaging structure of claim 1, wherein said lower LED package structure is bonded through adhering said light transmitting protection layer to said light transmitting filling material.

5. The composite light-emitting-diode (LED) packaging structure of claim 1, wherein said lower LED package structure is bonded through adhering said lower substrate to said upper substrate.

6. The composite light-emitting-diode (LED) packaging structure of claim 1, wherein said upper LED transparent chip is electrically connected to said upper substrate through a connection wire.

7. The composite light-emitting-diode (LED) packaging structure of claim 1, wherein said lower LED transparent chip is electrically connected to said lower substrate through a connection wire.

8. The composite light-emitting-diode (LED) packaging structure of claim 1, wherein said light transmitting filling material is formed integrally with said light transmitting protection layer.
